(19) United States
(12) Patent Application Publication
(10) Pub. No.: US 2025/0393364 A1
(43) Pub. Date: Dec. 25, 2025

(54) DISPLAY DEVICE

(71) Applicant: Samsung Display Co., Ltd., Yongin-Si (KR)

(72) Inventors: BYOUNGSANG SONG, Yongin-si (KR); Ki Nyeng KANG, Yongin-si (KR); JONGHWAN CHA, Yongin-si (KR)

(21) Appl. No.: 19/077,075

(22) Filed: Mar. 12, 2025

(30) Foreign Application Priority Data
Jun. 24, 2024 (KR) 10-2024-0081863

(51) Int. Cl. H10H 29/49; H01L 25/16; H10D 86/40; H10D 86/60

(52) U.S. Cl. CPC H10H 29/49; H01L 25/167; H10D 86/423; H10D 86/441; H10D 86/60

(57) ABSTRACT

A display device includes: a first semiconductor layer including a channel of a first transistor; a first gate insulating layer disposed on the first semiconductor layer; a first gate electrode disposed on the first gate insulating layer and overlapping the channel of the first transistor; a first interlayer insulating layer disposed on the first gate electrode; a second semiconductor layer disposed on the first interlayer insulating layer and including a channel of a second transistor; and a semiconductor pattern disposed on the first interlayer insulating layer and overlapping the first gate electrode. The semiconductor pattern comprises a first portion doped with a first concentration and a second portion doped with a second concentration that is different from the first concentration.

### CROSS-REFERENCE TO RELATED APPLICATION

This application claims priority to and the benefit of Korean Patent Application No. 10-2024-0081863 filed in the Korean Intellectual Property Office on Jun. 24, 2024, the entire contents of which are incorporated herein by reference.

### BACKGROUND

### 1. Field

The present disclosure relates to a display device.

### 2. Description of the Related Art

An organic light emitting display device includes two electrodes and an emission layer disposed between the two electrodes, and an electron injected from one electrode and a hole injected from another electrode combine in an organic emission layer to form an exciton. As the exciton changes from an exited state to a ground state, it can emit energy and emit light.

Such a display device includes a plurality of pixels, each including a light emitting diode, which is a self-emissive element, and a plurality of transistors and at least one capacitor may be formed for driving the light emitting diode in each pixel. The plurality of transistors basically includes a switching transistor and a driving transistor.

### SUMMARY

Embodiments are intended to simplify a manufacturing process of a display device and to improve the reliability of the display device.

A display device according to an embodiment includes: a substrate; a first semiconductor layer including a channel of a first transistor disposed on the substrate; a first gate insulating layer disposed on the first semiconductor layer; a first gate electrode disposed on the first gate insulating layer and overlapping the channel of the first transistor; a first interlayer insulating layer disposed on the first gate electrode; a second semiconductor layer disposed on the first interlayer insulating layer and including a channel of a second transistor; a semiconductor pattern disposed on the first interlayer insulating layer and overlapping the first gate electrode; a second gate insulating layer disposed on the second semiconductor layer and the semiconductor pattern; and a second gate electrode disposed on the second gate insulating layer and overlapping the channel of the second transistor. The semiconductor pattern comprises a first portion doped with a first concentration and a second portion doped with a second concentration different from the first concentration.

The first concentration may be greater than or equal to the second concentration.

The second concentration may be smaller than a doping concentration of the second semiconductor layer.

The first portion may be disposed outside the second portion.

The display device may include: a second interlayer insulating layer disposed on the second gate insulating layer and the second gate electrode; and an opening including a through-hole portion that penetrates the second interlayer insulating layer and overlaps the semiconductor pattern and an extension portion protruded from one end of the through-hole portion.

The extension portion may overlap the second portion and may not overlap the first portion.

A width of the extension portion may be less than or equal to a width of the semiconductor pattern.

The width of the extension portion may be a same as a width of the second portion.

The display device may further include a third interlayer insulating layer disposed on the second interlayer insulating layer and filling the opening.

The semiconductor pattern may be disposed on a same layer as the second semiconductor layer.

The semiconductor pattern may include an oxide semiconductor and the first semiconductor layer may include polycrystalline silicon.

The display device may further include: a connection electrode disposed on the first gate insulating layer and electrically connected with the first gate electrode; and a conductive pattern disposed on the second gate insulating layer and electrically connected with the connection electrode. The conductive pattern may overlap the semiconductor pattern.

The display device may further include: a second interlayer insulating layer disposed on the second gate insulating layer and the second gate electrode; a third interlayer insulating layer disposed on the second interlayer insulating layer; a first connection wire connected with the connection electrode by penetrating the third interlayer insulating layer; and a second connection wire connected between the first connection wire and the conductive pattern by penetrating the third interlayer insulating layer.

The display device may further include: a first data conductive layer connected with the first semiconductor layer by penetrating the second interlayer insulating layer; and a second data conductive layer connected with the first data conductive layer by penetrating the third interlayer insulating layer. The second data conductive layer may be disposed on a same layer as the second connection wire.

The conductive pattern and the second data conductive layer may include a same material.

A display device according to an embodiment may include: a substrate; a first semiconductor layer including a channel of a first transistor disposed on the substrate, and including polycrystalline silicon; a first gate insulating layer disposed on the first semiconductor layer; a first gate electrode disposed on the first gate insulating layer and overlapping the channel of the first transistor; a first interlayer insulating layer disposed on the first gate electrode; a second semiconductor layer disposed on the first interlayer insulating layer, including a channel of a second transistor, and including an oxide semiconductor; a semiconductor pattern disposed on the first interlayer insulating layer, overlapping the first gate electrode, and disposed on a same layer as the second semiconductor layer; a second gate insulating layer disposed on the second semiconductor layer and the semiconductor pattern; and a second gate electrode disposed on the second gate insulating layer and overlapping the channel of the second transistor. The semiconductor pattern includes a first portion doped with a first concentration and a second portion doped with a second concentration different from the first concentration.

The second concentration may be smaller than a doping concentration of the second semiconductor layer.

The display device may further include a second interlayer insulating layer disposed on the second gate insulating layer and the second gate electrode, and the display device may include an opening that includes a through-hole portion penetrating the second interlayer insulating layer and overlapping the semiconductor pattern and an extension portion protruded from one end of the through-hole portion.

The extension portion may overlap the second portion and may not overlap the first portion.

The display device may further include: a connection electrode disposed on the first gate insulating layer and electrically connected with the first gate electrode; and a conductive pattern disposed on the second gate insulating layer and electrically connected with the connection electrode. The conductive pattern overlaps the semiconductor pattern.

According to the embodiments, the manufacturing process of the display device can be simplified and the reliability of the elements of display devices can be improved.

### BRIEF DESCRIPTION OF THE DRAWINGS

FIG. 1 is a cross-sectional view of a part of a display device according to an embodiment.

FIG. 2 is an enlarged cross-sectional view of the region Q1 of FIG. 1.

FIG. 3 and FIG. 4 are circuit diagrams of a display device according to an embodiment.

FIG. 5 and FIG. 6 show a storage capacitor according to a display device according to some embodiments, and are cross-sectional views corresponding to the region Q1 of FIG. 1.

FIG. 7 and FIG. 8 are cross-sectional views of a part of the display device according to some embodiments.

FIGS. 9, 10, 11, 12, 13, 14, and 15 are process cross-sectional views of a middle stage in a manufacturing method of a display device according to an embodiment.

FIGS. 16, 17, 18, 19, and 20 are process cross-sectional views of a middle stage in a manufacturing method of a display device according to an embodiment.

FIG. 21 is a block diagram of an electronic device according to an embodiment.

FIG. 22 shows schematic diagrams of electronic devices according to various embodiments.

### DETAILED DESCRIPTION

Hereinafter, various embodiments of the present disclosure will be described in detail with reference to the attached drawings such that a person having ordinary skill in the art to which the present disclosure pertains can easily implement the inventive concept. The present disclosure may be implemented in many different forms and is not limited to the embodiments described herein.

The drawings and description are to be regarded as illustrative in nature and not restrictive. Like reference numerals designate like elements throughout the specification.

In addition, since the size and thickness of each configuration shown in the drawings are arbitrarily indicated for better understanding and ease of description, the present disclosure is not necessarily limited to the drawings. In the drawings, the thickness of layers, films, panels, regions, and the like, are exaggerated for clarity. In addition, in the drawings, the thickness of some layers and regions is exaggerated for better understanding and ease of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to mean positioned above or below the target element, and will not necessarily be understood to mean positioned “at an upper side” based on an opposite to gravity direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

In accordance with an embodiment, a display apparatus according to an embodiment is part of one of a smartphone, a mobile phone, a navigation device, a game player, a TV, a vehicle head unit, a notebook computer, a laptop computer, a tablet computer, a personal media player, a personal digital assistant, a center information display, a room mirror, and an entertainment device.

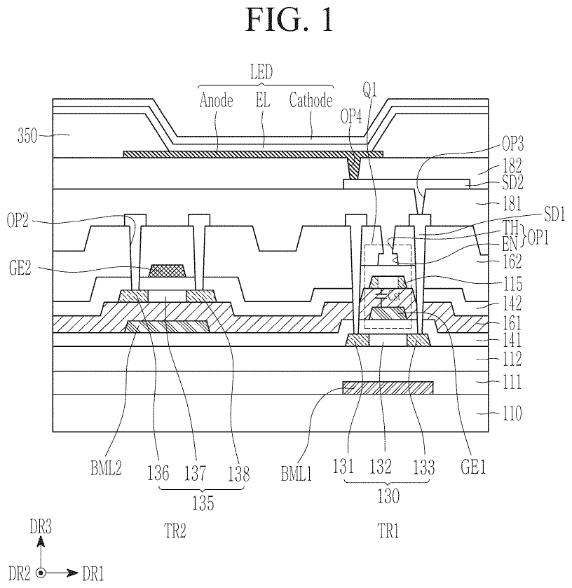

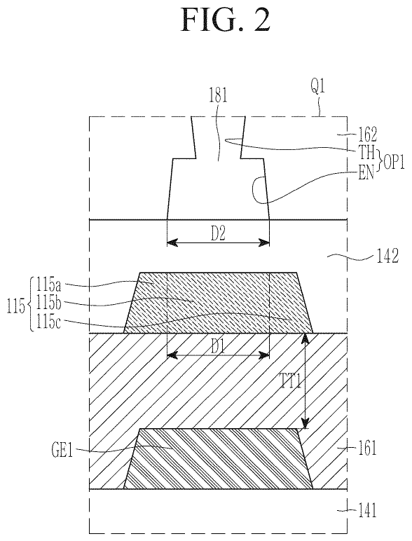

First, a display device according to an embodiment will be described with reference to FIG. 1 and FIG. 2.

FIG. 1 is a cross-sectional view of a part of a display device according to an embodiment. FIG. 2 is an enlarged cross-sectional view of the region Q1 of FIG. 1. In FIG. 1, a light emitting diode LED connected to a first transistor TR1, and a second transistor TR2 of a display device is mainly illustrated for better comprehension and ease of description. The first transistor TR1 may be a driving transistor. The second transistor TR2 may be a switching transistor.

Referring to FIG. 1, a display device according to an embodiment may include a substrate 110, a first semiconductor layer 130 disposed on the substrate 110, a first gate insulating layer 141 disposed on the first semiconductor layer 130, a first gate electrode GE1 disposed on the first gate insulating layer 141, a first interlayer insulating layer 161 disposed on the first gate electrode GE1, a second semiconductor layer 135 and a semiconductor pattern 115 disposed on the first interlayer insulating layer 161, a second gate insulating layer 142 disposed on the second semiconductor layer 135, and a second gate electrode GE2 disposed on the second gate insulating layer 142.

The substrate 110 may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. The substrate 110 may include a flexible material that can be bent or folded, and may be single-layered or multi-layered.

The display device according to an embodiment may further include a first metal layer BML1 disposed on the substrate 110. The first metal layer BML1 may overlap a first semiconductor layer 130, which will be described later. The first metal layer BML1, also called a lower shielding layer, may contain metals or metal alloys such as copper (Cu), molybdenum (Mo), aluminum (Al), and titanium (Ti), and may additionally contain amorphous silicon and may be formed of a single layer or multiple layers.

The display device according to an embodiment may further include a barrier layer 111 and a buffer layer 112 that cover the substrate 110 and the first metal layer BML1.

The barrier layer 111 may cover the substrate 110 and the first metal layer BML1, and the buffer layer 112 may be disposed on the barrier layer 111. The barrier layer 111 and the buffer layer 112 may have a single-layer or multi-layer structure. In FIG. 1, each of the barrier layer 111 and the buffer layer 112 is illustrated as a single layer, but may be multi-layered depending on embodiments. The barrier layer 111 may include, for example, silicon oxide, amorphous silicon, and the like. The barrier layer 111 may perform a function that prevents foreign substances from inflowing. The buffer layer 112 may include an organic insulating material or an inorganic insulating material. For example, the buffer layer 112 may include silicon nitride, silicon oxide, silicon acid nitride, and the like.

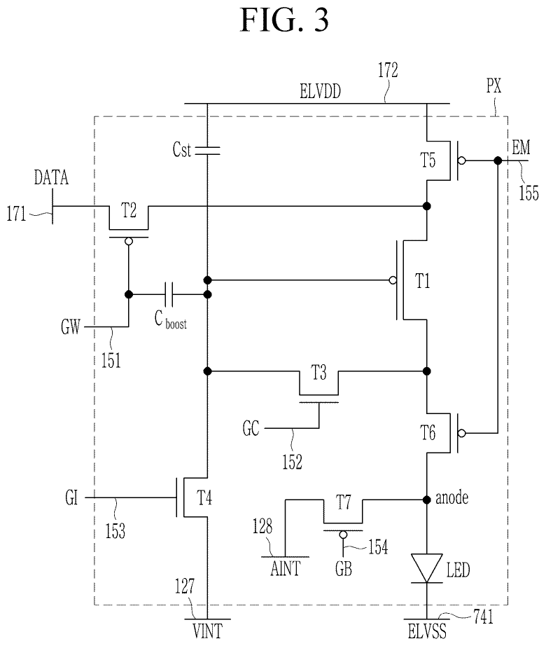

The first semiconductor layer 130 may be disposed on the buffer layer 112. The first semiconductor layer 130 may include polycrystalline silicon. That is, the first semiconductor layer 130 may be formed of polycrystalline semiconductor. The first semiconductor layer 130 may include a source region 131 and a drain region 133 along with a channel region 132. The source region 131 and the drain region 133 of the first semiconductor layer 130 may be regions having conductive layer characteristics on both sides of the channel region 132 through plasma treatment or doping. For example, the channel region 132 of the first semiconductor layer 130 may correspond to a channel of a first transistor T1 of an embodiment of FIG. 3. In addition, the first semiconductor layer 130 may include channels of a second transistor T2, a fifth transistor T5, a sixth transistor T6, and a seventh transistor T7 of the embodiment of FIG. 3. The source region 131 and the drain region 133 of the first semiconductor layer 130 may be connected to a first data conductive line SD1.

The first gate insulating layer 141 may be disposed on the first semiconductor layer 130. The first gate insulating layer 141 may include silicon nitride, silicon oxide, and the like.

The first gate electrode GE1 may be disposed on the first gate insulating layer 141. The first gate electrode GE1 may overlap the channel region of the first semiconductor layer 130 in a direction perpendicular to the substrate 110. The first gate electrode GE1 may correspond to a gate of the first transistor T1 of the embodiment of FIG. 3. In addition, in an embodiment, the first gate electrode GE1 may form a first storage electrode of a storage capacitor Cst of the embodiment of FIG. 3.

The first data conductive line SD1 connected with the first semiconductor layer 130, the first gate electrode GE1, and the source region 131 of the first semiconductor layer 130 and the first data conductive line SD1 connected with the drain region 133 of the first semiconductor layer 130 may form the first transistor TR1. The first transistor TR1 may be a driving transistor connected to a light emitting diode LED and may be formed of a transistor including a polycrystalline semiconductor.

The display device according to an embodiment may further include a second metal layer BML2 disposed on the first gate insulating layer 141.

The second metal layer BML2 may be disposed on the first gate insulating layer 141. The second metal layer BML2 may overlap with a second semiconductor layer 135, which will be described later. The second metal layer BML1 is also called a lower shielding layer and may perform protection of the second semiconductor layer 135 of the second transistor TR2. In an embodiment, the second metal layer BML2 may be disposed on the same layer as the first gate electrode GE1. That is, the second metal layer BML2 and the first gate electrode GE1 may be disposed on the first gate insulating layer 141. The second metal layer BML2 may be formed together with the first gate electrode GE1 in the same process. The second metal layer BML2 may contain the same material as the first gate electrode GE1. For example, the second metal layer BML2 may include a metal or metal alloy such as copper (Cu), molybdenum (Mo), aluminum (Al), or titanium (Ti), and may additionally include amorphous silicon and may be formed of a single layer or multiple layers.

The first interlayer insulating layer 161 may be disposed on the first gate electrode GE1 and the first gate insulating layer 141. The first interlayer insulating layer 161 may cover the first gate electrode GE1 and the second metal layer BML2. The first interlayer insulating layer 161 may include silicon nitride, silicon oxide, and the like. The first interlayer insulating layer 161 may be formed of a multilayer in which a layer containing silicon nitride and a layer containing silicon oxide are laminated. In this case, the layer including silicon nitride in the first interlayer insulating layer 161 may be disposed closer to the substrate 110 than a layer including silicon oxide. In an embodiment, the first interlayer insulating layer 161 may form a dielectric layer of the storage capacitor Cst. A detailed description of this will be provided later.

The second semiconductor layer 135 may be disposed on the first interlayer insulating layer 161. The second semiconductor layer 135 may overlap the second metal layer BML2 in a direction (e.g., a third direction DR3) that is perpendicular (e.g., perpendicular to a first direction DR1 and a second direction DR2) to the substrate 110. The second semiconductor layer 135 may be formed of an oxide semiconductor. The oxide semiconductor may include at least one of a primary metal oxide such as oxidation indium (In), oxidation tin (Sn), or oxidation zinc (Zn), a binary metal oxide such as In—Zn oxide, Sn—Zn oxide, Al—Zn oxide, Zn—Mg oxide, Sn—Mg oxide, In—Mg oxide or In—Ga oxide, and the like, a ternary metal oxide such as In—Ga—Zn type oxide, In—Al—Zn type oxide, In—Sn—Zn type oxide, Sn—Ga—Zn-based oxide, Al—Ga—Zn-based oxide, Sn—Al—Zn—based oxide, In—Hf—Zn-based oxide, In—La—Zn-based oxide, In—Ce—Zn-based oxide, In—Pr—Zn—based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, such as In—Ho—Zn oxide, In—Er—Zn oxide, In—Tm—Zn oxide, In—Yb—Zn oxide, or In—Lu—Zn oxide, and a quaternary metal oxide such as In—Sn—Ga—Zn oxide, In—Hf—Ga—Zn oxide, In—Al—Ga—Zn oxide, In—Sn—Al—Zn oxide, In—Sn—Hf—Zn oxide or In—Hf—Al—Zn oxide. For example, the second semiconductor layer 135 may include indium-gallium-zinc oxide (IGZO) among the In—Ga—Zn based oxides.

The second semiconductor layer 135 may include a channel region 137, a source region 136, and a drain region 138. The source region 136 and the drain region 138 of the second semiconductor layer 135 may be regions having conductive layer characteristics due to plasma treatment or doping of both sides of the source region 136. For example, at least a portion of the second semiconductor layer 135 may be doped with at least one of boron, phosphorus, argon, xenon, and krypton, but is not limited thereto. The channel region 137 of the second semiconductor layer 135 may correspond to channels of a third transistor T3 and a fourth transistor T4 of the embodiment of FIG. 3. The source region 136 and the drain region 138 of the second semiconductor layer 135 may be connected with the first data conductive line SD1.

The semiconductor pattern 115 may be disposed on the first interlayer insulating layer 161. The semiconductor pattern 115 may overlap the first gate electrode GE1 in a direction (e.g., the third direction DR3) perpendicular to the substrate 110. For example, the semiconductor pattern 115 may completely overlap the first gate electrode GE1, but is not limited thereto. Accordingly, the first interlayer insulating layer 161 may be disposed between the semiconductor pattern 115 and the first gate electrode GE1. The semiconductor pattern 115 may overlap the first semiconductor layer 130 in a direction (e.g., the third direction DR3) perpendicular to the substrate 110. The first interlayer insulating layer 161 may be disposed between the semiconductor pattern 115 and the first gate electrode GEL.

The semiconductor pattern 115 may be disposed in the same layer as the second semiconductor layer 135. That is, the semiconductor pattern 115 and the second semiconductor layer 135 may be disposed on the first interlayer insulating layer 161. The semiconductor pattern 115 may be formed together with the second semiconductor layer 135 in the same process. The semiconductor pattern 115 may include the same material as the second semiconductor layer 135. For example, the semiconductor pattern 115 may be formed of the same oxide semiconductor as the second semiconductor layer 135. For example, the semiconductor pattern 115 may include indium-gallium-zinc oxide (IGZO). In this case, the semiconductor pattern 115 may be doped with a dopant. The semiconductor pattern 115 may form a first storage electrode of the storage capacitor Cst.

In an embodiment, the semiconductor pattern 115 may be doped with a dopant. Here, the dopant may be at least one of boron, phosphorus, argon, xenon, and krypton, but is not limited thereto.

Further referring to FIG. 2, the semiconductor pattern 115 may include portions having different doping concentration. For example, the semiconductor pattern 115 may include a first portion 115a and a third portion 115c doped with a first concentration and a second portion 115b doped with a second concentration that is different from the first concentration.

The first portion 115a and the third portion 115c may be disposed outside the second portion 115b. For example, the second portion 115b may be disposed at a center of the semiconductor pattern 115, and the first portion 115a and the third portion 115c may be disposed at an edge of the semiconductor pattern 115, but is not limited thereto.

In an embodiment, the first concentration may be greater than or equal to the second concentration. For example, when the same material is doped in the first to third portions 115a to 115c of the semiconductor pattern 115, the first concentration of the doped material in the first portion 115a and the third portion 115c of the semiconductor pattern 115 may be greater than the second concentration of the doped material in the second portion 115b. As another example, the first portion 115a and the third portion 115c of the semiconductor pattern 115 may be doped with a first material and a second material different from the first material, and only the first material may be doped in the second portion 115b. In this case, since the first material is doped at substantially the same concentration in the first portion 115a to the third portion 115c, and the second material is further doped in the first portion 115a and the third portion 115c, the first concentration doped in the first portion 115a and the third portion 115c may be greater than the second concentration doped in the second portion 115b. Here, each of the first material and the second material may be at least one of boron, phosphorus, argon, xenon, and krypton, but is not limited thereto. Accordingly, the semiconductor pattern 115 may have conductive characteristics, and the semiconductor pattern 115 may form the first storage electrode of the storage capacitor Cst. In addition, the first portion 115a and the third portion 115c may be doped to substantially the same concentration, but is not limited thereto.

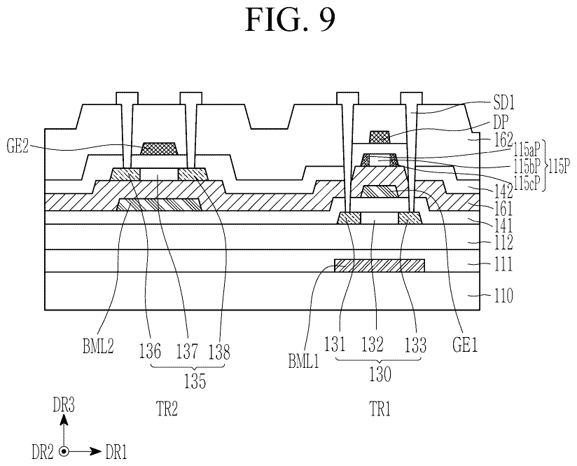

In an embodiment, the second concentration may be less than the doping concentration of the second semiconductor layer 135. This may be due to the process characteristic of forming a dummy electrode (e.g., see a dummy electrode DP in FIG. 9) on the semiconductor pattern 115, forming a second gate electrode GE2 on the second semiconductor layer 135, doping dopants into the semiconductor pattern 115 and the second semiconductor layer 135, removing the dummy electrode (e.g., see the dummy electrode DP in FIG. 9), and re-doping dopants into the exposed semiconductor pattern 115 and the second semiconductor layer 135. Accordingly, the doping concentration of the semiconductor pattern 115 may be varied, and the electric characteristics of the first storage electrode of the storage capacitor Cst may be easily designed. In addition, the first concentration may be substantially the same as the doping concentration of the second semiconductor layer 135, but is not limited thereto.

The semiconductor pattern 115, the first interlayer insulating layer 161, and the first gate electrode GE1 may form a capacitor. For example, the first gate electrode GE1 may form a second storage electrode of the storage capacitor Cst of the embodiment of FIG. 3, the semiconductor pattern 115 may form a first storage electrode of the storage capacitor Cst, and the first interlayer insulating layer 161 between the first gate electrode GE1 and the semiconductor pattern 115 may form a dielectric layer of the storage capacitor Cst.

As the semiconductor pattern 115, the first interlayer insulating layer 161, and the first gate electrode GE1 form the capacitor, a thickness TT1 of the first interlayer insulating layer 161 along the third direction DR3 may be determined by a desired capacitance value of the storage capacitor Cst. For example, the thickness TT1 along the third direction DR3 of the first interlayer insulating layer 161 may be 300 Å to 3000 Å. In other words, a length along the third direction DR3 between the semiconductor pattern 115 and the first gate electrode GE1 may be 300 Å to 3000 Å. In this range, the storage capacitor Cst may store and release an appropriate range of a gate voltage to drive the first transistor TR1, thereby improving the reliability of the display device according to an embodiment.

Referring back to FIG. 1, the second gate insulating layer 142 may be disposed on the second semiconductor layer 135 and the semiconductor pattern 115. The second gate insulating layer 142 may be disposed above the second semiconductor layer 135, the semiconductor pattern 115, and the first interlayer insulating layer 161. The second gate insulating layer 142 may cover the second semiconductor layer 135 and the semiconductor pattern 115. That is, the second gate insulating layer 142 may cover an upper surface and side surfaces of the second semiconductor layer 135 and an upper surface and side surfaces of the semiconductor pattern 115. The second gate insulating layer 142 may include silicon nitride, silicon oxide, and the like.

The second gate electrode GE2 may be disposed on the second gate insulating layer 142. The second gate electrode GE2 may overlap a channel region of the second semiconductor layer 135 in a direction perpendicular to the substrate 110.

The second semiconductor layer 135, the second gate electrode GE2, the first data conductive line SD1 connected to the source region 136 of the second semiconductor layer 135, and the first data conductive line SD1 connected to the drain region 138 of the second semiconductor layer 135 may form a second transistor TR2. The second transistor TR2 may be a switching transistor for switching of the first transistor TR1, and may be formed of a transistor including oxide semiconductor.

The display device according to an embodiment may further include a second interlayer insulating layer 162 and the first data conductive line SD1 disposed on the second gate insulating layer 142.

The second interlayer insulating layer 162 may be disposed on the second gate electrode GE2 and the second gate insulating layer 142. The second interlayer insulating layer 162 may cover the second gate electrode GE2. In addition, the first data conductive line SD1 may be disposed on the second interlayer insulating layer 162.

A first opening OP1 and a second opening OP2 may be formed in the second interlayer insulating layer 162. The first opening OP1 may overlap the semiconductor pattern 115 in a direction (e.g., the third direction DR3) perpendicular to the substrate 110, and the second opening OP2 may overlap the first semiconductor layer 130 and the second semiconductor layer 135 in a direction (e.g., the third direction DR3) perpendicular to the substrate 110. The second opening OP2 may be filled by the first data conductive line SD1. The first data conductive line SD1 may be connected with the source region 136 and the drain region 138 of the second semiconductor layer 135 and the source region 131 and the drain region 133 of the first semiconductor layer 130 through the second opening OP2. In other words, the first data conductive line SD1 may be connected to the second semiconductor layer 135 through the second interlayer insulating layer 162 and the second gate insulating layer 142. The first data conductive line SD1 may be connected to the first semiconductor layer 130 through the second interlayer insulating layer 162, second gate insulating layer 142, the first interlayer insulating layer 161, and the first gate insulating layer 141. The first data conductive line SD1 may be configured as a source electrode and a drain electrode of the transistor.

Further referring to FIG. 2, the first opening OP1 may overlap the semiconductor pattern 115 in a direction (e.g., the third direction DR3) perpendicular to the substrate 110. The first opening OP1 may overlap the first semiconductor layer 130 in a direction (e.g., the third direction DR3) perpendicular to the substrate 110

For example, the first opening OP1 may completely overlap the semiconductor pattern 115 in a direction (e.g., the third direction DR3) perpendicular to the substrate 110, but is not limited thereto. As another example, at least a portion of the first opening OP1 may overlap the semiconductor pattern 115 in a direction (e.g., the third direction DR3) perpendicular to the substrate 110. In an embodiment, the maximum width along the first direction DR1 of the first opening OP1 may be less than or equal to the maximum width along the first direction DR1 of the semiconductor pattern 115. The first opening OP1 may be filled by a third interlayer insulating layer 181.

The first opening OP1 may include a through-hole portion TH extending in a direction (e.g., the third direction DR3) perpendicular to the substrate 110 and an extension portion EN extending from one end of the through-hole portion TH in the first direction DR1. The extension portion EN may overlap with the second portion 115b of the semiconductor pattern 115 in a direction (e.g., in the third direction DR3, sometimes called in a plan view) perpendicular to the substrate 110, and may not overlap with the first portion 115a and the third portion 115c in a direction (e.g., the third direction DR3) perpendicular to the substrate 110. A second width D2 along the first direction DR1 of the extension portion EN may be substantially the same as a first width D1 along the first direction DR1 of the second portion 115b. That is, the second width D2 along the first direction DR1 of the extension portion EN may be smaller than or equal to the width along the first direction DR1 of the semiconductor pattern 115. The extension portion EN may correspond to a space where the dummy electrode (e.g., see the dummy electrode DP in FIG. 9) is removed.

The display device according to an embodiment may further include a third interlayer insulating layer 181 and a fourth interlayer insulating layer 182 disposed on the second interlayer insulating layer 162.

The third interlayer insulating layer 181 may be disposed on the interlayer insulating layer 162. The third interlayer insulating layer 180 may cover the first data conductive line SD1. The third interlayer insulating layer 181 may fill the first opening OP1. A third opening OP3 may be formed in the third interlayer insulating layer 180. The third opening OP3 of the third interlayer insulating layer 180 may be filled with a second data conductive line SD2. The fourth interlayer insulating layer 182 may be disposed on the third interlayer insulating layer 181.

The display device according to an embodiment may further include the light emitting diode LED disposed on the fourth interlayer insulating layer 182. The light emitting diode LED may include an anode Anode, a light-emitting device layer EL, and a cathode Cathode.

The anode Anode may be disposed on the fourth interlayer insulating layer 182. The anode Anode may be connected with the second data conductive line SD2 through the fourth opening OP4 of the fourth interlayer insulating layer 182.

A partitioning wall 350 may be disposed on the anode Anode. An opening may be formed in the partitioning wall 350, and the opening of the partitioning wall 350 may extend to and overlap the anode Anode. The light-emitting device layer EL may be disposed on the partitioning wall 350 and the anode Anode. The cathode Cathode may be disposed on the light-emitting device layer EL. The anode Anode, the light-emitting device layer EL, and the cathode Cathode form the light emitting diode LED.

The first gate electrode GE1, the semiconductor pattern 115, and the first interlayer insulating layer 161 of the display device according to an embodiment may form the storage capacitor Cst of the embodiment of FIG. 3. For example, the semiconductor pattern 115 may form the first storage electrode of the storage capacitor Cst, the first gate electrode GE1 may form the second storage electrode of the storage capacitor Cst, and the first interlayer insulating layer 161 between the semiconductor pattern 115 and the first gate electrode GE1 may form the dielectric layer of the storage capacitor Cst. Since the semiconductor pattern 115 is formed together with the second semiconductor layer 135 in the same layer as the second semiconductor layer 135 during the process of forming the second semiconductor layer 135, the process of forming the first storage electrode separately can be omitted. Accordingly, the process of forming the display device can be simplified.

In addition, the semiconductor pattern 115 may include portions having different doping concentrations. A second concentration doped in the second portion 115b of the semiconductor pattern 115 may be less than or equal to a first concentration doped in the first portion 115a and the third portion 115c. Accordingly, the electric characteristics of the first storage electrode can be controlled, and the electric characteristics of the storage capacitor Cst can be easily designed.

Next, referring to FIG. 3, a circuit diagram of the display device according to an embodiment will be described.

FIG. 3 is a circuit diagram of the display device according to an embodiment. One pixel of the display device according to an embodiment includes the plurality of transistors T1, T2, T3, T4, T5, T6, and T7 connected to a plurality of signal lines, the storage capacitor Cst, a boost capacitor Cboost, and a light emitting diode LED. Depending on embodiments, the boost capacitor Cboost may be omitted.

The display device according to an embodiment includes a display area where an image is displayed, and a pixel PX may be arranged in various formats in the display area.

A plurality of signal lines 127, 128, 151, 152, 153, 154, 155, 171, 172, and 741 are connected to the pixel PX. The plurality of signal lines include a first initialization voltage line 127, a second initialization voltage line 128, a scan line 151, a reverse scan line 152, an initialization control line 153, a bypass control line 154, a light emission control line 155, a data line 171, a driving voltage line 172, and a common voltage line 741.

The scan line 151 is connected to a gate driver (not shown) and transmits a scan signal GW to the second transistor T2. The reverse scan line 152 may be applied with a voltage of opposite polarity to a voltage applied to the scan line 151 at the same timing as the signal of the scan line 151. For example, when a high voltage is applied to the scan line 151, a low voltage may be applied to the reverse scan line 152. The reverse scan line 152 transmits a reverse scan signal GC to the third transistor T3.

The initialization control line 153 transmits an initialization control signal GI to the fourth transistor T4. The bypass control line 154 transmits a bypass signal GB to the seventh transistor T7. The bypass control line 154 may be formed of a scan line 151 at the next stage. The light emission control line 155 transmits a light emission control signal EM to the fifth transistor T5 and the sixth transistor T6.

The data line 171 is a wire transmitting a data voltage DATA generated in a data driver (not shown), and luminance of the light emitting diode LED is changed according to the data voltage DATA applied to the pixel PX.

The driving voltage line 172 applies a driving voltage ELVDD. The first initialization voltage line 127 transmits a first initialization voltage VINT, and the second initialization voltage line 128 transmits a second initialization voltage AINT. The common voltage line 741 applies a common voltage ELVSS to a cathode of the light emitting diode LED. In the present embodiment, voltages applied to the driving voltage line 172, the first and second initialization voltage lines 127 and 128, and the common voltage line 741 may each be a constant voltage.

Hereinafter, a structure and a connection relationship of the plurality of transistors will be described in detail.

The driving transistor T1 may have a P-type transistor characteristic and may include a polycrystalline semiconductor. The driving transistor T1 is a transistor that controls the intensity of the current output to the anode of the light emitting diode LED according to the data voltage DATA applied to the gate electrode of the driving transistor T1. Since the brightness of the light emitting diode LED is controlled by the intensity of the driving current output to the anode of the light emitting diode LED, the luminance of the light emitting diode LED can be controlled by the data voltage DATA applied to the pixel PX. To this end, the first electrode of the driving transistor T1 is arranged to receive the driving voltage ELVDD and is connected to the driving voltage line 172 via the fifth transistor T5. In addition, a first electrode of the driving transistor T1 is connected to a second electrode of the second transistor T2 and also receives the data voltage DATA. The second electrode of the driving transistor T1 is arranged to output a current toward the light emitting diode LED and thus is connected with the anode of the light emitting diode LED via the sixth transistor T6. In addition, the second electrode of the driving transistor T1 transmits the data voltage DATA applied to the first electrode to the third transistor T3. The gate electrode of the driving transistor T1 is connected with one electrode (hereinafter, also called a first storage electrode) of the storage capacitor Cst. Accordingly, the voltage of the gate electrode of the driving transistor T1 changes according to the voltage stored in the storage capacitor Cst, and the driving current output by the driving transistor T1 changes accordingly. In addition, the storage capacitor Cst also serves to maintain the voltage of the gate electrode of the driving transistor T1 constant during one frame.

The second transistor T2 may have a P-type transistor characteristic and may include a polycrystalline semiconductor. The second transistor T2 is a transistor that receives the data voltage DATA into the pixel PX. A gate electrode of the second transistor T2 is connected to the scan line 151 and a first electrode of the boost capacitor Cboost. A first electrode of the second transistor T2 is connected with the data line 171. A second electrode of the second transistor T2 is connected with the first electrode of the driving transistor T1. When the second transistor T2 is turned on by a low voltage of the scan signal GW transmitted through the scan line 151, the data voltage DATA transmitted through the data line 171 is transmitted to the first electrode of the driving transistor T1.

The third transistor T3 may have an N-type transistor characteristic and may include an oxide semiconductor. The third transistor T3 electrically connects the second electrode of driving transistor T1 and the gate electrode of the driving transistor T1. The third transistor T3 is a transistor that allows the data voltage DATA to be transmitted as a changed compensation voltage through the driving transistor T1 to the second storage electrode of the storage capacitor Cst. A gate electrode of the third transistor T3 is connected to the reverse scan line 152, and a first electrode of the third transistor T3 is connected to the second electrode of the driving transistor T1. The second electrode of the third transistor T3 is connected to the second storage electrode of the storage capacitor Cst, the gate electrode of the driving transistor T1, and a second electrode of the boost capacitor Cboost. The third transistor T3 is turned on by a high voltage among the reverse scan signal GC received through the reverse scan line 152, connects the gate electrode of the driving transistor T1 and the second electrode of the driving transistor T1, and transmits the voltage applied to the gate electrode of the driving transistor T1 to the second storage electrode of the storage capacitor Cst and stores it in the storage capacitor Cst.

The fourth transistor T4 may have an N-type transistor characteristic and may include an oxide semiconductor. The fourth transistor T4 serves to initialize the gate electrode of the driving transistor T1 and the second storage electrode of the storage capacitor Cst. A gate electrode of the fourth transistor T4 is connected to the initialization control line 153, and a first electrode of the fourth transistor T4 is connected to the first initialization voltage line 127. A second electrode of the fourth transistor T4 is connected to the second storage electrode of the storage capacitor Cst, the gate electrode of the driving transistor T1, and the second electrode of the boost capacitor Cboost via the second electrode of the third transistor T3. The fourth transistor T4 is turned on by a high voltage of the initialization control signal GI received through the initialization control line 153, and in this case, the first initialization voltage VINT is transmitted to the gate electrode of the driving transistor T1 and the second storage electrode of the storage capacitor Cst. Accordingly, the voltage of the gate electrode of the driving transistor T1 and the storage capacitor Cst are initialized.

The fifth transistor T5 may have a P-type transistor characteristic and may contain a polycrystalline semiconductor. The fifth transistor T5 serves to transmit the driving voltage ELVDD to the driving transistor T1. A gate electrode of the fifth transistor T5 is connected to the light emission control line 155, a first electrode of the fifth transistor T5 is connected to the driving voltage line 172, and a second electrode of the fifth transistor T5 is connected to the first electrode of the driving transistor T1.

The sixth transistor T6 may have a P-type transistor characteristic and may contain a polycrystalline semiconductor. The sixth transistor T6 transmits the driving current output from the driving transistor T1 to the light emitting diode LED. A gate electrode of the sixth transistor T6 is connected to the light emission control line 155, a first electrode of the sixth transistor T6 is connected to the second electrode of the driving transistor T1, and a second electrode of the sixth transistor T6 is connected to the anode of the light emitting diode LED.

The seventh transistor T7 may have a P-type transistor characteristic and may contain a polycrystalline semiconductor. The seventh transistor T7 serves to initialize the anode of the light emitting diode LED. A gate electrode of the seventh transistor T7 is connected to the bypass control line 154, a first electrode of the seventh transistor T7 is connected to the anode of the light emitting diode LED, and a second electrode of the seventh transistor T7 is connected to the second initialization voltage line 128. When the seventh transistor T7 is turned on by a low voltage of the bypass signal GB, the second initialization voltage AINT is applied to the anode of the light emitting diode LD for initialization.

The storage capacitor Cst may include a first storage electrode and a second storage electrode. The first storage electrode is connected to the driving voltage line 172, and the second storage electrode is connected to the gate electrode of the driving transistor T1, the second electrode of the third transistor T3, and the second electrode of the fourth transistor T4. As a result, the second storage electrode determines the voltage of the gate electrode of the driving transistor T1, and receives the data voltage through the second electrode of the third transistor T3 or the initialization voltage through the second electrode of the fourth transistor T4.

In the above, it is described that one pixel includes seven transistors T1 to T7, one storage capacitor Cst, and one boost capacitor Cboost, but it is not limited thereto, and the number of transistors, the number of capacitors, and their connection relationships may be changed in various ways.

In the present embodiment, the driving transistor T1 may include a polycrystalline semiconductor. In addition, the third transistor T3 and the fourth transistor T4 may include an oxide semiconductor. The second transistor T2, the fifth transistor T5, the sixth transistor T6, and the seventh transistor T7 may contain polycrystalline semiconductors. However, it is not limited thereto, and at least one or more of the second transistor T2, the fifth transistor T5, the sixth transistor T6, and the seventh transistor T7 may include an oxide semiconductor. In the present embodiment, the third transistor T3 and the fourth transistor T4 include different semiconductor materials from the driving transistor T1, thereby enabling more stable operation and improving reliability.

In an embodiment, the third transistor T3 and the fourth transistor T4 may have a structure similar to the second transistor TR2 in FIG. 1 in the embodiment illustrated in FIG. 1 and FIG. 2. In addition, the driving transistor T1 in the present embodiment may have a structure similar to the first transistor TR1 in FIG. 1 in the embodiment illustrated in FIG. 1 and FIG. 2. In addition, the storage capacitor Cst may be formed of the first gate electrode GE1 of FIG. 1, the semiconductor pattern 115 of FIG. 1, and the first interlayer insulating layer 161 of FIG. 1 in the embodiment illustrated in FIG. 1 and FIG. 2.

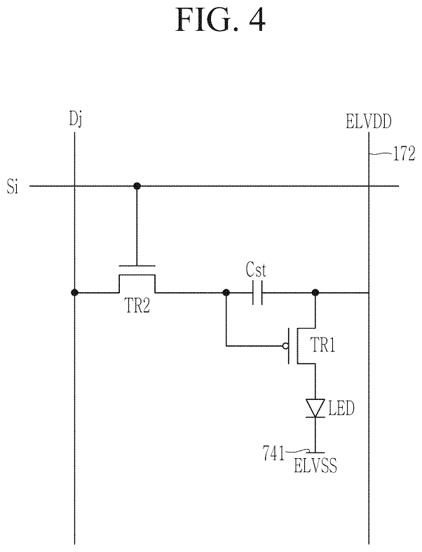

Next, referring to FIG. 4, a circuit diagram of a display device according to an embodiment will be described.

FIG. 4 is a circuit diagram of a display device according to an embodiment.

Referring to FIG. 4, one pixel may include a first transistor TR1 for controlling a light emitting diode LED, a second transistor TR2 switching the first transistor TR1, and a storage capacitor Cst connected to a driving voltage line 172. The second transistor TR2, which is a switching transistor, may include an oxide semiconductor, and the first transistor TR1, which is a driving transistor, may include a polycrystalline semiconductor.

The second transistor TR2 may include a gate electrode, a source electrode, and a drain electrode. The gate electrode of the second transistor TR2 may be connected to an i-th scan wire Si, and the source electrode may be connected to a j-th data wire Dj. The drain electrode of the second transistor TR2 may be connected to the gate electrode of the first transistor TR1. The second transistor TR2 may transmit a data signal applied to the j-th data wire Dj to the first transistor TR1 according to a scanning signal applied to the i-th scan wire Si.

The first transistor TR1 may include a gate electrode, a source electrode, and a drain electrode. The gate electrode of the first transistor TR1 may be connected to the second transistor TR2, the source electrode may be connected to a driving voltage line 172, and the drain electrode may be connected to the light emitting diode LED.

The light emitting diode LED may include a light emitting layer and an anode and a cathode facing each other with the light emitting layer interposed therebetween. The anode may be connected to the drain electrode of the first transistor TR1. The cathode may be connected to a common voltage line 741 and thus at common voltage ELVSS may be applied. The light emitting layer may display an image by emitting or not emitting light according to an output signal of the first transistor TR1.

Here, the light emitted from the light emitting layer may vary depending on a material of the light emitting layer, and may be colored light or white light.

In an embodiment, the storage capacitor Cst is connected between the gate electrode and the source electrode of the first transistor TR1, and may charge and maintain a data signal input to the gate electrode of the first transistor TR1.

It is described that one pixel includes two transistors TR1 and TR2 in FIG. 4, but is not limited thereto, and may include one transistor and a capacitor, or three or more transistors and two or more capacitors. In an embodiment, the storage capacitor Cst may be formed of a first gate electrode GE1 of FIG. 1, a semiconductor pattern 115 of FIG. 1, and a first interlayer insulating layer 161 of FIG. 1, as in the embodiment shown in FIG. 1 and FIG. 2.

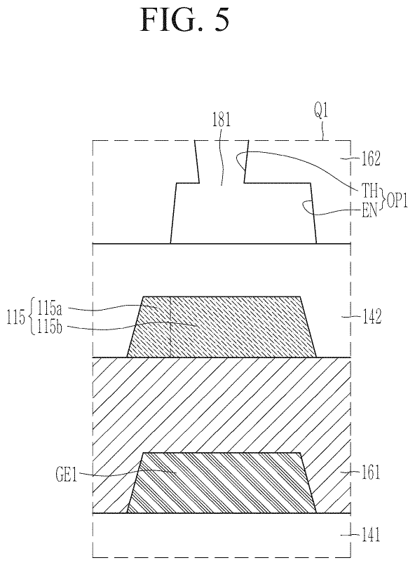

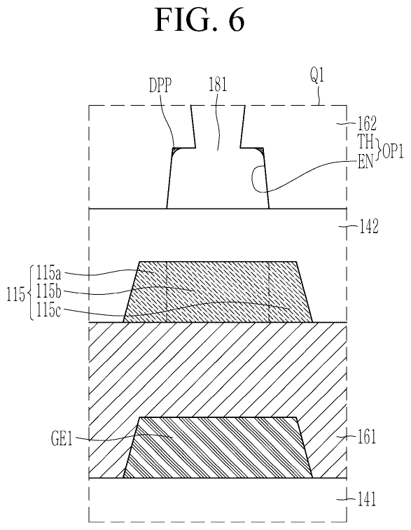

Hereinafter, a storage capacitor of a display device according to some embodiments will be described with reference to FIG. 5 and FIG. 6.

FIG. 5 and FIG. 6 show a storage capacitor according to a display device according to some embodiments, and are cross-sectional views corresponding to the region Q1 of FIG. 1. A display device according to embodiments shown in FIG. 5 and FIG. 6 is almost the same as the display device according to the embodiments shown in FIG. 1 to FIG. 4, and therefore description of the same parts is omitted.

Referring to FIG. 5, a semiconductor pattern 115 of a display device according to some embodiments may not include a third portion. That is, the semiconductor pattern 115 may include only a first portion 115a doped with a first concentration and a second portion 115b doped with a second concentration. In this case, the first concentration may be greater than or equal to the second concentration. In this case, the first concentration may be substantially the same as a doping concentration of the second semiconductor layer 135, but is not limited thereto.

In some embodiments, a first opening OP1 may overlap the second portion 115b in a direction (e.g., the third direction DR3) perpendicular to the substrate 110 and not overlap the first portion 115a in a direction (e.g., the third direction DR3) perpendicular to the substrate 110.

Referring to FIG. 6, the display device according to some embodiments may further include a dummy pattern DPP disposed in the first opening OP1.

The dummy pattern DPP may be disposed in the first opening OP1. Specifically, the dummy pattern DPP may be disposed at one end of an extension portion EN of the first opening OP1. The dummy pattern DPP may overlap the semiconductor pattern 115 in a direction (e.g., the third direction DR3) perpendicular to the substrate 110. For example, the dummy pattern DPP may overlap the second portion 115b of the semiconductor pattern 115 in a direction (e.g., the third direction DR3) perpendicular to the substrate 110 and not overlap the first portion 115a and the third portion 115c in a direction (e.g., the third direction DR3) perpendicular to the substrate 110. The dummy pattern DPP may include the same material as the second gate electrode GE2. For example, the dummy pattern DPP may include the same conductive material as the second gate electrode GE2. The dummy pattern DPP may be a part where at least a portion of the dummy electrode (e.g., see the dummy electrode DP in FIG. 9) is not removed during the process of removing the dummy electrode (e.g., see the dummy electrode DP in FIG. 9).

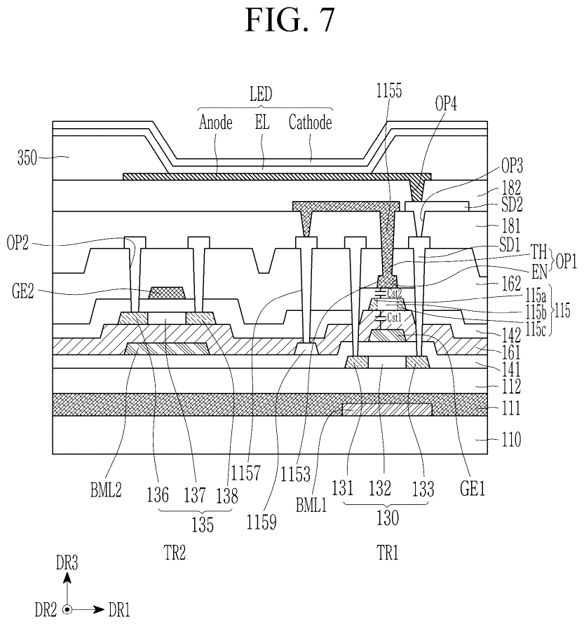

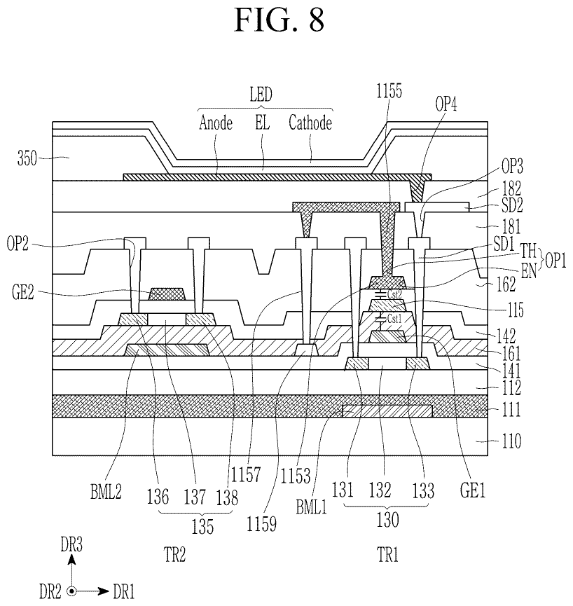

Hereinafter, a storage capacitor of the display device according to some embodiments will be described with reference to FIG. 7 and FIG. 8.

FIG. 7 and FIG. 8 are cross-sectional views of a part of the display device according to some embodiments. The display device according to the embodiment shown in FIG. 7 and FIG. 8 is almost the same as the display device according to the embodiment shown in FIG. 1 to FIG. 4, and therefore a description for the same portion will be omitted. The embodiment of FIG. 7 and FIG. 8 is different from the embodiment of FIG. 1 to FIG. 4 in that a storage capacitor Cst includes a plurality of capacitors Cst1 and Cst2.

Referring to FIG. 7 and FIG. 8, the display device according to some embodiments may further include a connection electrode 1159 disposed on the first gate insulating layer 141 and a conductive pattern 1153 disposed on the semiconductor pattern 115.

The connection electrode 1159 may be disposed on the first gate insulating layer 141. The connection electrode 1159 may be electrically connected with a first gate electrode GE1. The connection electrode 1159 may be disposed on the same layer as the first gate electrode GE1. The connection electrode 1159 may be formed together with the first gate electrode GE1 in the same process. The connection electrode 1159 may be integrally formed with the first gate electrode GE1, and may be connected with the first gate electrode GE1 through separate connection wires. The connection electrode 1159 may contain the same material as the first gate electrode GE1. For example, the connection electrode 1159 may include a metal such as copper (Cu), molybdenum (Mo), aluminum (Al), titanium (Ti), and the like of a metal alloy, but is not limited thereto.

The conductive pattern 1153 may be disposed on the semiconductor pattern 115. The conductive pattern 1153 may be disposed on a second gate insulating layer 142. The conductive pattern 1153 may be disposed between a second interlayer insulating layer 162 and the second gate insulating layer 142. The conductive pattern 1153 may overlap the semiconductor pattern 115 in a direction (e.g., the third direction DR3) perpendicular to the substrate 110. For example, as shown in FIG. 7, the conductive pattern 1153 may overlap the second portion 115b of the semiconductor pattern 115 in a direction (e.g., the third direction DR3) perpendicular to the substrate 110 and may not overlap the first portion 115a and the third portion 115c in a direction (e.g., the third direction DR3) perpendicular to the substrate 110. As another example, as shown in FIG. 8, the conductive pattern 1153 may completely overlap the semiconductor pattern 115 in a direction (e.g., the third direction DR3) perpendicular to the substrate 110. In this case, a doping concentration within the semiconductor pattern 115 may be uniform, but is not limited thereto. The conductive pattern 1153 may be formed together with the second data conductive line SD2 in the same process. The conductive pattern 1153 may contain the same material as the second data conductive line SD2.

In some embodiments, connection wires 1157 and 1155 connecting between the conductive pattern 1153 and the connection electrode 1159 may further be included. The first connection wire 1157 may be disposed on the second interlayer insulating layer 162. The first connection wire 1157 may be connected with the connection electrode 1159 by penetrating the second interlayer insulating layer 162, the second gate insulating layer 142, and the first interlayer insulating layer 161. The first connection wire 1157 may be disposed in the same layer as the first data conductive line SD1. The first connection wire 1157 may be formed together with the first data conductive line SD1 in the same process. The first connection wire 1157 may contain the same material as the first data conductive line SD1.

The second connection wire 1155 may be disposed on a third interlayer insulating layer 181. The second connection wire 1155 may be connected with the first connection wire 1157 by penetrating the third interlayer insulating layer 181, and may be connected with the conductive pattern 1153 by penetrating the third interlayer insulating layer 181 and the second interlayer insulating layer 162. The second connection wire 1155 may be disposed on the same layer as the second data conductive line SD2. The second connection wire 1155 may be formed together with the second data conductive line SD2 through the same process. The second connection wire 1155 may contain the same material as the second data conductive line SD2. The second connection wire 1155 may be formed integrally with the conductive pattern 1153. That is, the second connection wire 1155 may include the same material as the conductive pattern 1153. The semiconductor pattern 115, the conductive pattern 1153, and the second gate insulating layer 142 between the semiconductor pattern 115 and the semiconductor pattern 115 may form a part of the storage capacitor Cst.

That is, in some embodiments, the storage capacitor Cst may include a first storage capacitor Cst1 and a second storage capacitor Cst2. As in the embodiment of FIGS. 7-8, the first gate electrode GE1, the semiconductor pattern 115, and the first interlayer insulating layer 161 between the first gate electrode GE1 and the semiconductor pattern 115 may form the first storage capacitor Cst1, and the semiconductor pattern 115, the conductive pattern 1153, and the second gate insulating layer 142 between the semiconductor pattern 115 and the conductive pattern 1153 may form the second storage capacitor Cst2. In this case, the conductive pattern 1153 may be electrically connected with the first gate electrode GE1 through the connection electrode 1159. Therefore, the first storage capacitor Cst1 and the second storage capacitor Cst2 may be coupled in parallel, and the capacitance of the storage capacitor Cst may increase.

Hereinafter, referring to FIG. 9 to FIG. 15, a manufacturing method of a display device according to an embodiment will be described.

FIG. 9 to FIG. 15 are process cross-sectional views of a middle stage in a manufacturing method of a display device according to an embodiment.

First, referring to FIG. 9, first, a first metal layer BML1, a barrier layer 111, and a buffer layer 112 may be formed on a substrate 110, and then a first semiconductor layer 130 may be formed on the buffer layer 112.

The substrate 110 may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. The substrate 110 may include a flexible material that can be bent or folded, and may be single-layered or multi-layered. The first metal layer BML1, also called a lower shielding layer, may contain metals or metal alloys such as copper (Cu), molybdenum (Mo), aluminum (Al), and titanium (Ti), and may additionally contain amorphous silicon and may be formed of a single layer or multiple layers.

The barrier layer 111 may cover the substrate 110 and the first metal layer BML1, and the buffer layer 112 may be disposed on the barrier layer 111. The barrier layer 111 and the buffer layer 112 may have a single-layer or multi-layer structure. Although it is illustrated in FIG. 9 that each of the barrier layer 111 and the buffer layer 112 is formed as a single layer, but may be multi-layered depending on the embodiment. The barrier layer 111 may include, for example, silicon oxide, amorphous silicon, and the like. The barrier layer 111 may perform a function that prevents foreign substances from inflowing. The buffer layer 112 may include an organic insulating material or an inorganic insulating material. For example, the buffer layer 112 may include silicon nitride, silicon oxide, silicon acid nitride, and the like.

The first semiconductor layer 130 may be disposed on the buffer layer 112. A process of forming the first semiconductor layer 130 may be performed by forming a polycrystalline silicon material layer, forming an etching mask such as a photoresist, and then performing an etching process. The first semiconductor layer 130 may include polycrystalline semiconductor. That is, the first semiconductor layer 130 may be formed of polycrystalline semiconductor.

Next, a first gate insulating layer 141 may be disposed on the first semiconductor layer 130. The first gate insulating layer 141 may be formed to cover an upper surface of the buffer layer 112 and upper and side surfaces of the first semiconductor layer 130. The first gate insulating layer 141 may include silicon nitride, silicon oxide, and the like.

Next, the first gate electrode GE1 and a second metal layer BML2 may be formed on the first gate insulating layer 141.

The first gate electrode GE1 may overlap a channel region of the first semiconductor layer 130 in a direction perpendicular to the substrate 110. The first gate electrode GE1 may correspond to the gate of the first transistor T1 of the embodiment of FIG. 3. In addition, in an embodiment, the first gate electrode GE1 may form a first storage electrode of the storage capacitor Cst of the embodiment of FIG. 3.

The second metal layer BML2 may be disposed on the first gate insulating layer 141. The second metal layer BML2 may be formed so as not to overlap with the first semiconductor layer 130. In an embodiment, the second metal layer BML2 may be disposed in the same layer as the first gate electrode GE1. That is, the second metal layer BML2 and the first gate electrode GE1 may be disposed on the first gate insulating layer 141. The second metal layer BML2 may be formed together with the first gate electrode GE1 in the same process. The second metal layer BML2 may include the same material as the first gate electrode GE1. For example, the second metal layer BML2 may include a metal such as copper (Cu), molybdenum (Mo), aluminum (Al), titanium (Ti), and the like or a metal alloy and may additionally include amorphous silicon and may be formed of a single layer or multiple layers.

Next, a plasma treatment or implant process may be performed within the first semiconductor layer 130 to dope at least a portion of the first semiconductor layer 130. For example, the first semiconductor layer 130 may not have a portion that overlaps with the first gate electrode GE1 and may have a portion that does not overlap with the first gate electrode GE1 doped. Accordingly, at least a portion of the first semiconductor layer 130 may be doped to form a source region 131 and a drain region 133 having conductive characteristics, and a portion that is not doped by the first gate electrode GE1 may be formed as a channel region 132.

Next, a first interlayer insulating layer 161 may be formed on the first gate electrode GE1 and the second metal layer BML2, and a preliminary semiconductor pattern 115P and a second semiconductor layer 135 may be formed on the first interlayer insulating layer 161. The preliminary semiconductor pattern 115P and the second semiconductor layer 135 may be formed of an oxide semiconductor. For example, the preliminary semiconductor pattern 115P and the second semiconductor layer 135 may include an indium-gallium-zinc oxide (IGZO). The preliminary semiconductor pattern 115P may overlap the first gate electrode GE1 in a direction (e.g., the third direction DR3) perpendicular to the substrate 110. The second semiconductor layer 135 may overlap the second metal layer BML2 in a direction (e.g., the third direction DR3) perpendicular to the substrate 110.

Next, a second gate insulating layer 142 is formed on the preliminary semiconductor pattern 115P and the second semiconductor layer 135, and a second gate electrode GE2 and a dummy electrode DP may be formed on the second gate insulating layer 142.

The second gate electrode GE2 may be formed to overlap the second semiconductor layer 135 in a direction (e.g., the third direction DR3) perpendicular to the substrate 110. The dummy electrode DP may be formed to overlap the preliminary semiconductor pattern 115P in a direction (e.g., the third direction DR3) perpendicular to the substrate 110. The dummy electrode DP may be disposed on at least a portion of the preliminary semiconductor pattern 115P. The dummy electrode DP may be formed in the same layer as the second gate electrode GE2. The dummy electrode DP may contain the same conductive material as the second gate electrode GE2. For example, the dummy electrode DP may contain a metal such as copper (Cu), molybdenum (Mo), aluminum (Al), or titanium (Ti) or a metal alloy thereof. A process of forming the second gate electrode GE2 and the dummy electrode DP may be performed by forming a conductive material layer and performing an etching process after forming an etching mask such as a photoresist.

Next, a plasma treatment or implant process may be performed on the second semiconductor layer 135 and the preliminary semiconductor pattern 115P to dope at least a portion of the second semiconductor layer 135 and the preliminary semiconductor pattern 115P. For example, in the second semiconductor layer 135, a portion overlapping the second gate electrode GE2 may not be doped, and a portion not overlapping the second gate electrode GE2 may be doped. Accordingly, at least a portion of the second semiconductor layer 135 may be doped to form a source region 136 and a drain region 138 having conductive characteristics, and an undoped portion formed by the second gate electrode GE2 may be formed as a channel region 137. In addition, in the preliminary semiconductor pattern 115P, a portion overlapping the dummy electrode DP may not be doped and a portion not overlapping the dummy electrode DP may be doped. Accordingly, at least a portion of the preliminary semiconductor pattern 115P may be doped to form a first portion 115aP and a third portion 115cP, and an undoped second portion 115bP may be formed by the dummy electrode DP.

Next, a second interlayer insulating layer 162 may be formed on the first gate insulating layer 141, the dummy electrode DP, and the second gate electrode GE2, and a first data conductive line SD1 may be formed on the second interlayer insulating layer 162. The first data conductive line SD1 may be connected to the source region 131 and drain region 133 of the first semiconductor layer 130 and the source region 136 and drain region 138 of the second semiconductor layer 135 through the second interlayer insulating layer 162.

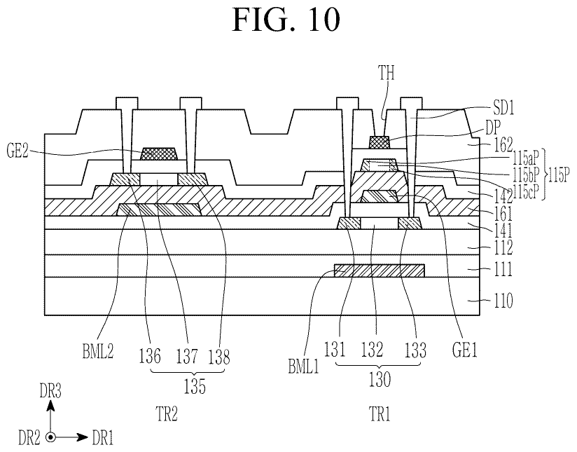

Referring to FIG. 10, the second interlayer insulating layer 162 may be etched to form a through-hole portion TH exposing the dummy electrode DP. A process of forming the through-hole portion TH may be performed using a dry etching process after forming an etching mask such as photoresist, but is not limited thereto. An upper surface of the dummy electrode DP may be exposed by the through-hole portion TH.

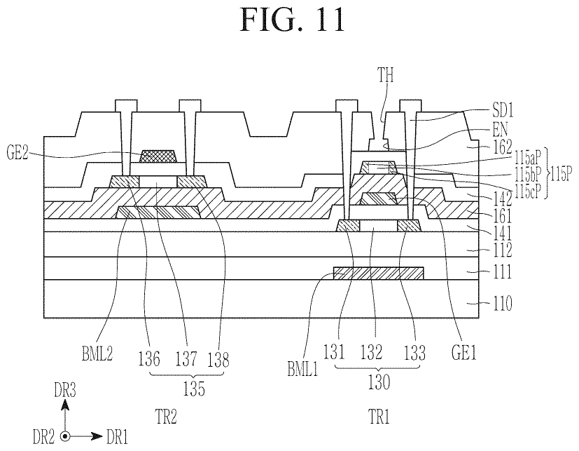

Referring to FIG. 11, the dummy electrode DP exposed by the through-hole portion TH may be removed to form an extension portion EN. A process of removing the dummy electrode DP may be performed using a dry etching method, but is not limited thereto. The dummy electrode DP may include a material having etch selectivity with respect to the second interlayer insulating layer 162 and the second gate insulating layer 142. Accordingly, the second interlayer insulating layer 162 and the second gate insulating layer 142 may not be etched during the process of removing the dummy electrode DP.

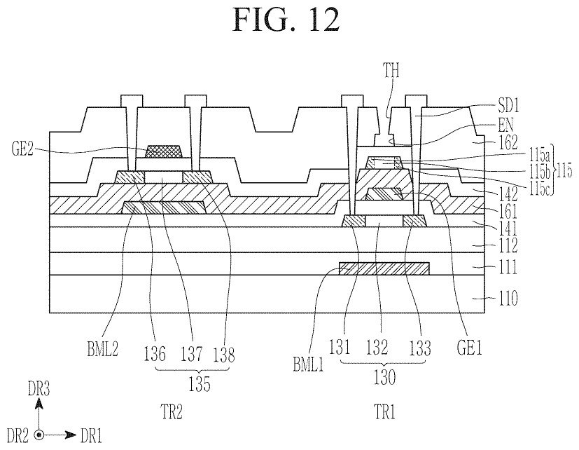

Referring to FIG. 12, the preliminary semiconductor pattern 115P may be doped by performing a plasma treatment or implant process within the preliminary semiconductor pattern 115P.

As the dummy electrode DP is removed and the extension portion EN is formed on the preliminary semiconductor pattern 115P, the conductive layer may not be disposed on the upper surface of the preliminary semiconductor pattern 115P. Accordingly, the entire preliminary semiconductor pattern 115P may be doped with a dopant. The dopant may include at least one of boron, phosphorus, argon, xenon, and krypton, but is not limited thereto.

Accordingly, the semiconductor pattern 115 may include portions having different doping concentrations. For example, in the semiconductor pattern 115, a first portion 115a and a third portion 115c doped with a first concentration and a second portion 115b doped with a second concentration different from the first concentration may be formed.

In an embodiment, the first concentration may be greater than or equal to the second concentration. For example, when the same material is doped in the first to third portions 115a to 115c of the semiconductor pattern 115, the first concentration of the doped material in the first portion 115a and the third portion 115c of the semiconductor pattern 115 may be greater than the second concentration of the doped material in the second portion 115b. As another example, the first portion 115a and the third portion 115c of the semiconductor pattern 115 may be doped with a first material and a second material different from the first material, and only the first material may be doped in the second portion 115b. In this case, since the first material is doped at substantially the same concentration in the first portion 115a to the third portion 115c, and the second material is further doped in the first portion 115a and the third portion 115c, the first concentration doped in the first portion 115a and the third portion 115c may be greater than the second concentration doped in the second portion 115b. Here, each of the first material and the second material may be at least one of boron, phosphorus, argon, xenon, and krypton, but is not limited thereto. Accordingly, the semiconductor pattern 115 may have conductive characteristics, and the semiconductor pattern 115 may form the first storage electrode of the storage capacitor Cst. In addition, the first portion 115a and the third portion 115c may be doped to substantially the same concentration, but is not limited thereto.

In this case, the second semiconductor layer 135 may be doped together. Accordingly, the second concentration may be smaller than the doping concentration doped into the second semiconductor layer 135. In addition, the first concentration may be substantially the same as the doping concentration of the second semiconductor layer 135, but is not limited thereto.

The semiconductor pattern 115, the first interlayer insulating layer 161, and the first gate electrode GE1 may form a capacitor. For example, the first gate electrode GE1 may form a second storage electrode of the storage capacitor Cst of the embodiment of FIG. 3, the semiconductor pattern 115 may form a first storage electrode of the storage capacitor Cst, and a first interlayer insulating layer 161 between the first gate electrode GE1 and the semiconductor pattern 115 may form a dielectric layer of the storage capacitor Cst.

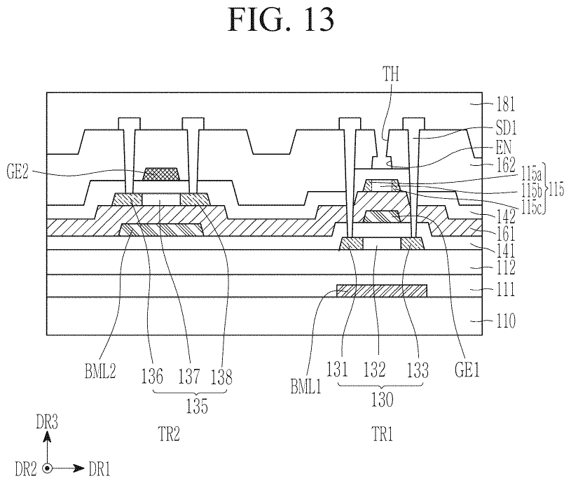

Referring to FIG. 13, a third interlayer insulating layer 181 may be formed on the second interlayer insulating layer 162. The third interlayer insulating layer 181 may fill the extension portion EN and the through-hole portion TH.

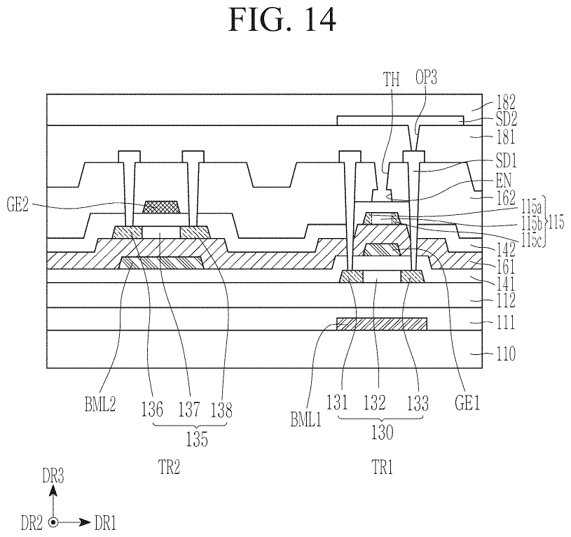

Referring to FIG. 14, a second data conductive line SD2 may be formed on the third interlayer insulating layer 181, and a fourth interlayer insulating layer 182 may be formed on the second data conductive line SD2 and the third interlayer insulating layer 181. The second data conductive line SD2 may be connected to the first data conductive line SD1 through a third opening OP3 penetrating the third interlayer insulating layer 181.

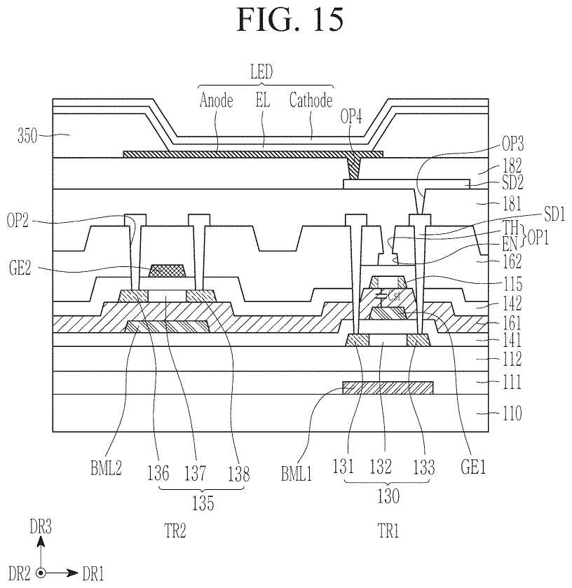

Referring to FIG. 15, a light emitting diode LED may be formed on the fourth interlayer insulating layer 182. Specifically, an anode Anode may be formed on the fourth interlayer insulating layer 182, and a partitioning wall 350 may be formed on the anode Anode. An opening is formed in the partitioning wall 350, and the opening of the partitioning wall 350 may overlap the anode Anode. A light-emitting device layer EL is formed on the partitioning wall 350 and the anode Anode and a cathode Cathode is formed on the light-emitting device layer EL such that the display device according to an embodiment can be formed.

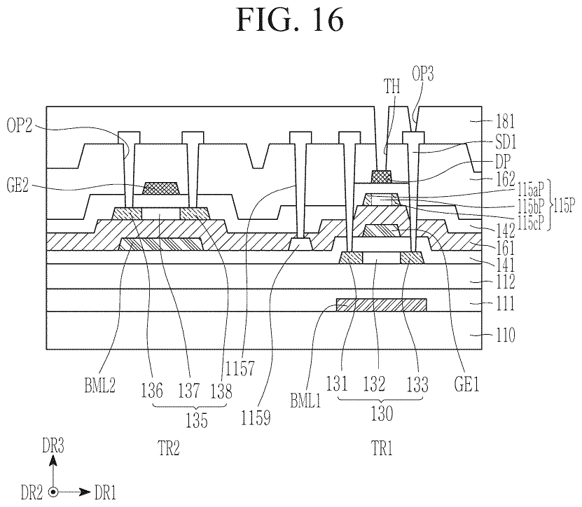

Hereinafter, referring to FIG. 16 to FIG. 20, a manufacturing method of a display device according to some embodiments will be described.

FIG. 16 to FIG. 20 are process cross-sectional views of a middle stage in a manufacturing method of a display device according to an embodiment. A manufacturing method of a display device according to the embodiment illustrated in FIG. 16 to FIG. 20 is substantially the same as the manufacturing method of the display device according to the embodiment illustrated in FIG. 9 to FIG. 15, and therefore the description of the same parts is omitted.

Referring to FIG. 16, a first metal layer BML1, a barrier layer 111, and a buffer layer 112 may be formed on a substrate 110, and a first semiconductor layer 130 may be formed on the buffer layer 112. A first gate insulating layer 141 may be formed on the first semiconductor layer 130. A first gate electrode GE1 and a second metal layer BML2 may be formed on the first gate insulating layer 141.

In some embodiments, a connection electrode 1159 may be formed on the first gate insulating layer 141. The connection electrode 1159 may be formed together with the first gate electrode GE1 and the second metal layer BML2 in the same process. The connection electrode 1159 may contain the same material as the first gate electrode GE1 and the second metal layer BML2.

A first interlayer insulating layer 161 may be formed on the first gate electrode GE1 and the second metal layer BML2, and a preliminary semiconductor pattern 115P and a second semiconductor layer 135 may be formed on the first interlayer insulating layer 161. A second gate insulating layer 142 may be formed on the preliminary semiconductor pattern 115P and the second semiconductor layer 135, and a second gate electrode GE2 and a dummy electrode DP may be formed on the second gate insulating layer 142. A semiconductor pattern 115 may be formed by doping the preliminary semiconductor pattern 115P. A second interlayer insulating layer 162 may be formed on the second gate insulating layer 142, the dummy electrode DP, and the second gate electrode GE2, and a first data conductive line SD1 may be formed on the second interlayer insulating layer 162. The first data conductive line SD1 may be connected to a source region 131 and a drain region 133 of the first semiconductor layer 130 and a source region 136 and a drain region 138 of the second semiconductor layer 135 through the second interlayer insulating layer 162. The process for this is substantially the same as the manufacturing method of the display device according to the embodiment of FIG. 9 to FIG. 15, and therefore no further description will be provided.

In some embodiments, a first connection wire 1157 may be formed on the second interlayer insulating layer 162. The first connection wire 1157 may be connected to the connection electrode 1159 by passing through the second interlayer insulating layer 162, the second gate insulating layer 142, and the first interlayer insulating layer 161. The first connection wire 1157 may be formed together with the first data conductive line SD1 through the same process. The first connection wire 1157 may contain the same material as the first data conductive line SD1.

Next, a third interlayer insulating layer 181 may be formed on the second interlayer insulating layer 162, and a through-hole portion TH penetrating the third interlayer insulating layer 181 and the second interlayer insulating layer 162 may be formed. A process of forming the through-hole portion TH may be performed using a dry etching process after forming an etching mask such as photoresist, but is not limited thereto. An upper surface of the dummy electrode DP may be exposed by the through-hole portion TH.

In this case, a third opening OP3 that penetrates the third interlayer insulating layer 181 and exposes the first data conductive line SD1 may be formed together. That is, the through-hole portion TH and the third opening OP3 may be formed simultaneously by the same process.

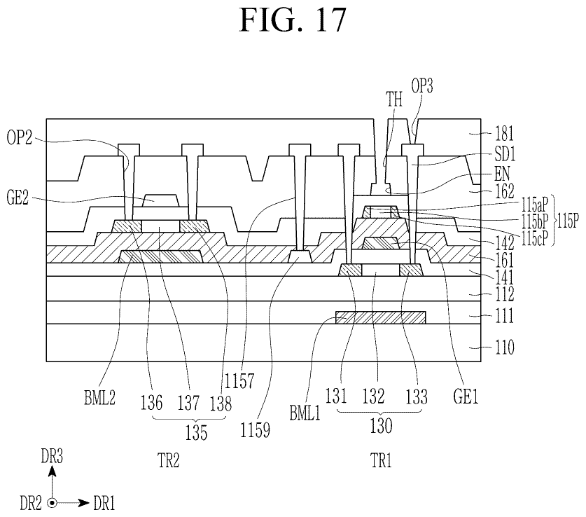

Referring to FIG. 17, an extension portion EN may be formed be removing the dummy electrode DP exposed by the through-hole portion TH. A process of removing the dummy electrode DP may be performed using a dry etching method, but is not limited thereto. The dummy electrode DP may include a material having etch selectivity with respect to the third interlayer insulating layer 181, the second interlayer insulating layer 162, and the second gate insulating layer 142. Accordingly, the third interlayer insulating layer 181, the second interlayer insulating layer 162, and the second gate insulating layer 142 may not be etched during the process of removing the dummy electrode DP.

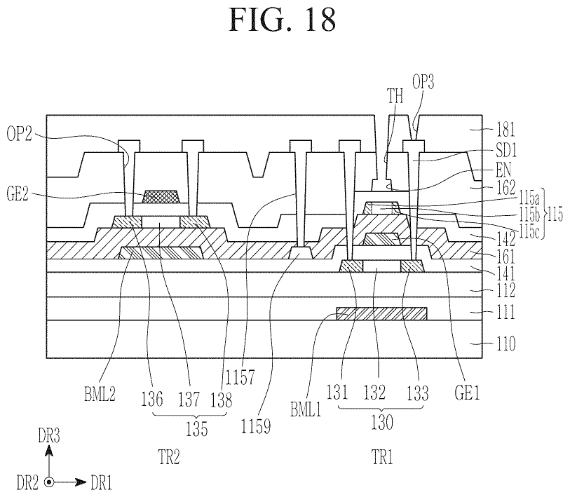

Referring to FIG. 18, the preliminary semiconductor pattern 115P may be doped by performing a plasma treatment or implant process within the preliminary semiconductor pattern 115P.

As the dummy electrode DP is removed and the extension portion EN is formed on the preliminary semiconductor pattern 115P, the conductive layer may not be disposed on the upper surface of the preliminary semiconductor pattern 115P. Accordingly, the entire preliminary semiconductor pattern 115P may be doped with a dopant. The dopant may include at least one of boron, phosphorus, argon, xenon, and krypton, but is not limited thereto.

Accordingly, the semiconductor pattern 115 may include portions having different doping concentrations. For example, in the semiconductor pattern 115, a first portion 115a and a third portion 115c doped with a first concentration and a second portion 115b doped with a second concentration different from the first concentration may be formed. In this case, the first concentration may be greater than or equal to the second concentration. In this case, the second semiconductor layer 135 may be doped together. Accordingly, the second concentration may be smaller than the doping concentration doped into the second semiconductor layer 135. In addition, the first concentration may be substantially the same as the doping concentration of the second semiconductor layer 135, but is not limited thereto. The description related to this is omitted because it is substantially the same as the manufacturing method of the display device according to the embodiment of FIG. 9 to FIG. 15.

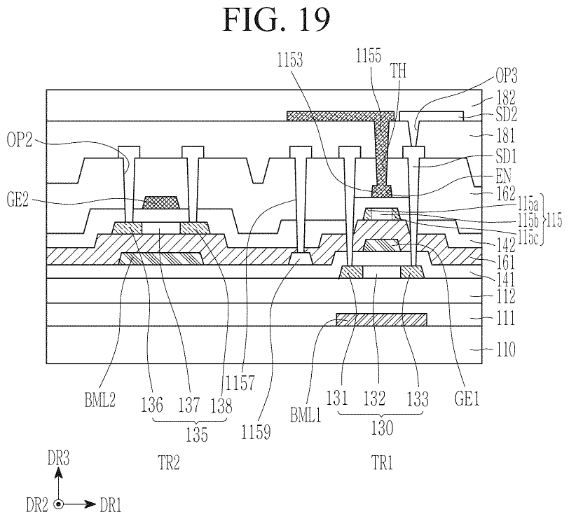

Referring to FIG. 19, first, a conductive pattern 1153 is formed in the extension portion EN, and then a second connection wire 1155 connected with the conductive pattern 1153 may be formed on the third interlayer insulating layer 181.

The conductive pattern 1153 may be formed in the extension portion EN. That is, the conductive pattern 1153 may be formed on the second gate insulating layer 142. The conductive pattern 1153 may overlap the semiconductor pattern 115 in a direction (e.g., the third direction DR3) perpendicular to the substrate 110. For example, as in the embodiment shown in FIG. 7, the conductive pattern 1153 may overlap the second portion 115b of the semiconductor pattern 115 in a direction (e.g., the third direction DR3) perpendicular to the substrate 110 and may not overlap the first portion 115a and the third portion 115c in a direction (e.g., the third direction DR3) perpendicular to the substrate 110. As another example, as in the embodiment shown in FIG. 8, the conductive pattern 1153 may completely overlap the semiconductor pattern 115 in a direction (e.g., the third direction DR3) perpendicular to the substrate 110.

The second connection wire 1155 may be formed on the third interlayer insulating layer 181. The second connection wire 1155 may be connected with the first connection wire 1157 by penetrating the third interlayer insulating layer 181, and may be connected with the conductive pattern 1153 by penetrating the third interlayer insulating layer 181 and the second interlayer insulating layer 162. The second connection wire 1155 may be disposed on the same layer as the second data conductive line SD2. The second connection wire 1155 may be formed together with the second data conductive line SD2 through the same process. The second connection wire 1155 may contain the same material as the second data conductive line SD2. The second connection wire 1155 may be formed integrally with the conductive pattern 1153. That is, the second connection wire 1155 may include the same material as the conductive pattern 1153. Next, a fourth interlayer insulating layer 182 may be formed on the third interlayer insulating layer 181.

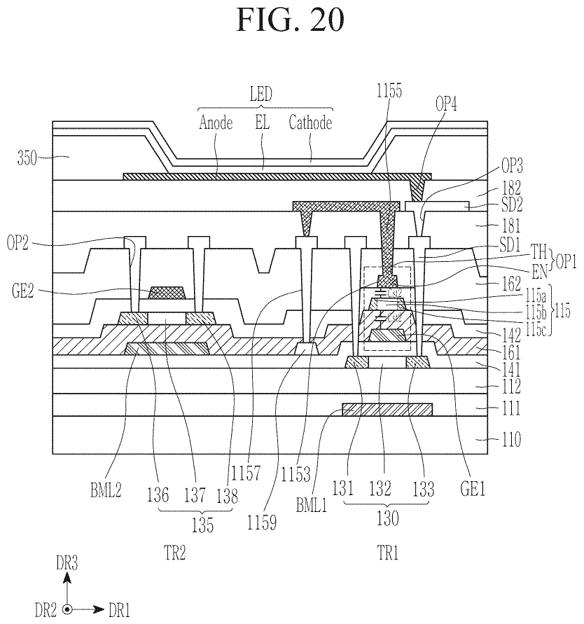

Referring to FIG. 20, a light emitting diode LED may be formed on the fourth interlayer insulating layer 182. Specifically, an anode Anode may be formed on the fourth interlayer insulating layer 182, and a partitioning wall 350 may be formed on the anode Anode. An opening is formed in the partitioning wall 350, and the opening of the partitioning wall 350 may overlap the anode Anode. A light-emitting device layer EL is formed on the partitioning wall 350 and the anode Anode and a cathode Cathode is formed on the light-emitting device layer EL such that the display device according to an embodiment can be formed.

A display device according to an embodiment may be applied to various electronic devices. An electronic device according to an embodiment may include the display device, and may further include modules or devices having additional functions other than the display device.

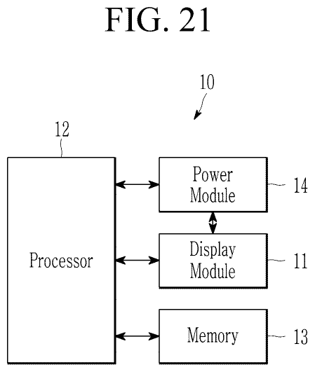

FIG. 21 is a block diagram of an electronic device according to an embodiment. Referring to FIG. 21, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for operations of the processor 12 or the display module 11. When the processor 12 executes an application stored in the memory 13, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 10 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 10 that are not part of the display device.

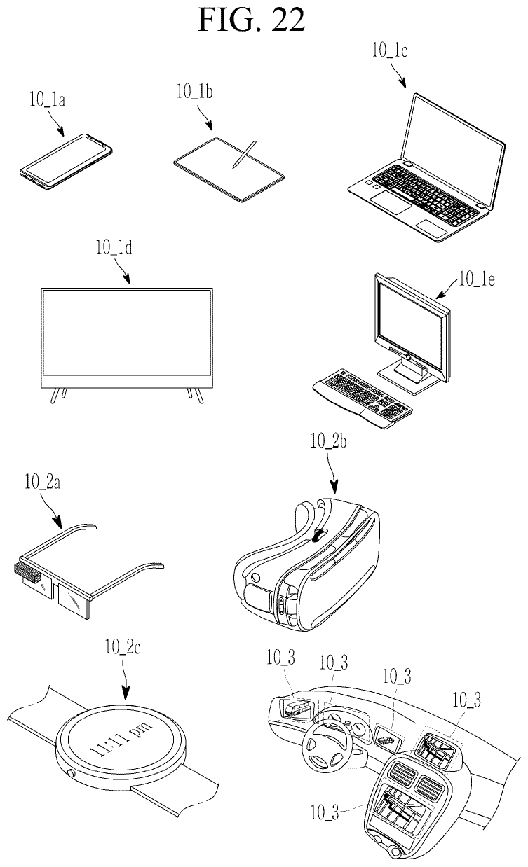

FIG. 22 shows schematic diagrams of electronic devices according to various embodiments.

Referring to FIG. 22, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

While this disclosure has been described in connection with what is presently considered to be practical embodiments, it is to be understood that the inventive concept is not limited to the disclosed embodiments. On the contrary, it is intended to cover various modifications and equivalent arrangements included within the spirit and scope of the appended claims.

### DESCRIPTION OF SYMBOLS

110: substrate
130: first semiconductor layer
GE1: first gate electrode
115: semiconductor pattern
135: second semiconductor layer
GE2: second gate electrode
141: first gate insulating layer
142: second gate insulating layer
161: first interlayer insulating layer
162: second interlayer insulating layer
181: third interlayer insulating layer

What is claimed is:

1. A display device comprising:
a substrate;
a first semiconductor layer including a channel of a first transistor disposed on the substrate;
a first gate insulating layer disposed on the first semiconductor layer;
a first gate electrode disposed on the first gate insulating layer and overlapping the channel of the first transistor;
a first interlayer insulating layer disposed on the first gate electrode;
a second semiconductor layer disposed on the first interlayer insulating layer and including a channel of a second transistor;
a semiconductor pattern disposed on the first interlayer insulating layer and overlapping the first gate electrode;
a second gate insulating layer disposed on the second semiconductor layer and the semiconductor pattern; and
a second gate electrode disposed on the second gate insulating layer and overlapping the channel of the second transistor,
wherein the semiconductor pattern comprises a first portion doped with a first concentration and a second portion doped with a second concentration different from the first concentration.

2. The display device of claim 1, wherein:
the first concentration is greater than or equal to the second concentration.

3. The display device of claim 1, wherein:
the second concentration is smaller than a doping concentration of the second semiconductor layer.

4. The display device of claim 1, comprising:
a second interlayer insulating layer disposed on the second gate insulating layer and the second gate electrode and
an opening including a through-hole portion that penetrates the second interlayer insulating layer and overlaps the semiconductor pattern and an extension portion protruded from one end of the through-hole portion.

5. The display device of claim 4, wherein:
the extension portion overlaps the second portion and does not overlap the first portion.

6. The display device of claim 4, wherein:
a width of the extension portion is less than or equal to a width of the semiconductor pattern.

7. The display device of claim 6, wherein:
the width of the extension portion is a same as a width of the second portion.

8. The display device of claim 4, further comprising a third interlayer insulating layer disposed on the second interlayer insulating layer and filling the opening.

9. The display device of claim 1, wherein:
the semiconductor pattern is disposed on a same layer as the second semiconductor layer.

10. The display device of claim 9, wherein:
the semiconductor pattern comprises an oxide semiconductor and the first semiconductor layer comprises polycrystalline silicon.

11. The display device of claim 1, further comprising:
a connection electrode disposed on the first gate insulating layer and electrically connected with the first gate electrode; and
a conductive pattern disposed on the second gate insulating layer and electrically connected with the connection electrode,
wherein the conductive pattern overlaps the semiconductor pattern.

12. The display device of claim 11, further comprising:
a second interlayer insulating layer disposed on the second gate insulating layer and the second gate electrode;
a third interlayer insulating layer disposed on the second interlayer insulating layer;
a first connection wire connected with the connection electrode by penetrating the third interlayer insulating layer; and
a second connection wire connected between the first connection wire and the conductive pattern by penetrating the third interlayer insulating layer.

13. The display device of claim 12, further comprising:
a first data conductive layer connected with the first semiconductor layer by penetrating the second interlayer insulating layer; and
a second data conductive layer connected with the first data conductive layer by penetrating the third interlayer insulating layer,
wherein the second data conductive layer is disposed on a same layer as the second connection wire.

14. The display device of claim 13, wherein:
the conductive pattern and the second data conductive layer comprise a same material.

15. A display device comprising:
a substrate;
a first semiconductor layer including a channel of a first transistor disposed on the substrate, and including polycrystalline silicon;
a first gate insulating layer disposed on the first semiconductor layer;
a first gate electrode disposed on the first gate insulating layer and overlapping the channel of the first transistor;
a first interlayer insulating layer disposed on the first gate electrode;
a second semiconductor layer disposed on the first interlayer insulating layer, including a channel of a second transistor, and including an oxide semiconductor;
a semiconductor pattern disposed on the first interlayer insulating layer, overlapping the first gate electrode, and disposed on a same layer as the second semiconductor layer;
a second gate insulating layer disposed on the second semiconductor layer and the semiconductor pattern; and
a second gate electrode disposed on the second gate insulating layer and overlapping the channel of the second transistor,
wherein the semiconductor pattern comprises a first portion doped with a first concentration and a second portion doped with a second concentration different from the first concentration.

16. The display device of claim 15, wherein:
the second concentration is smaller than a doping concentration of the second semiconductor layer.

17. The display device of claim 15, further comprising a second interlayer insulating layer disposed on the second gate insulating layer and the second gate electrode, and
the display device comprises an opening that includes a through-hole portion penetrating the second interlayer insulating layer and overlapping the semiconductor pattern and an extension portion protruded from one end of the through-hole portion.

18. The display device of claim 17, wherein:
the extension portion overlaps the second portion and does not overlap the first portion.

19. The display device of claim 15, further comprising:
a connection electrode disposed on the first gate insulating layer and electrically connected with the first gate electrode; and
a conductive pattern disposed on the second gate insulating layer and electrically connected with the connection electrode,
wherein the conductive pattern overlaps the semiconductor pattern.

20. The display apparatus of claim 1,
wherein the display apparatus is part of one of a smartphone, a mobile phone, a navigation device, a game player, a TV, a vehicle head unit, a notebook computer, a laptop computer, a tablet computer, a personal media player, a personal digital assistant, a center information display, a room mirror, and an entertainment device.
